(19) United States
(12) Patent Application Publication
(10) Pub. No.: US 2005/0084610 A1
(43) Pub. Date: Apr. 21, 2005

(54) Atmospheric pressure molecular layer CVD

(76) Inventor: Simon I. Selitser, Fremont, CA (US)

Correspondence Address: GREGORY SMITH & ASSOCIATES, 3900 NEWPARK MALL ROAD, 3RD FLOOR, NEWARK, CA, 94560, US

(21) Appl. No.: 10/640,750

(22) Filed: Aug. 13, 2003

Related U.S. Application Data
(60) Provisional application No. 60/402,871, filed on Aug. 13, 2002.

(51) Int. Cl. C23C 16/00

(52) U.S. Cl. 427/248.1

(57) ABSTRACT

An Atomic Layer CVD process and apparatus deposits single and or multiple minelayers of material sequentially at atmospheric pressure. Sequential monolayer depositions are separated in time and in space by combinations of physical barriers and/or gas curtains and/or by physical movement of substrates from one deposition chamber or location to another Pulse and/or continuous flows of reactant and purge gases are used in alternate embodiments of the present invention. Reactant injection, purge gas flow and exhaust flows at separated deposition chambers or locations are controlled by coordination of dedicated gas manifolds and control systems for each spatially or temporally separated deposition process or location.

This application claims priority based on Provisional Application Ser. No. 60/402,871 Filing Date Aug. 13, 2002

### BACKGROUND OF THE INVENTION

Atomic Layer Deposition (ALD) or Atomic Layer CVD (ALCVD) has been explored since the late 70's, mainly for formation of various compound semiconductor single-crystal materials, where it is valued for the ability to deposit good crystalline materials at unusually low temperature. The essence of the method is the use of adsorption to saturate the surface of a substrate with monolayer of one reactant, and then separately expose the surface to a second reactant, which reactivates the surface (and in the case of compound, may deposit a monolayer of the second constituent).

In conventional CVD, all reactants required for film growth are simultaneously exposed to a wafer surface, where they continuously deposit a thin film. CVD deposition rates can be surface-limited at lower temperatures, or flux-limited at higher temperatures where deposition rates are relatively higher. ALCVD works quite differently from conventional CVD techniques. Instead of mixing two or more reactant gases inside the deposition chamber, where they react on the wafer surface, ALCVD introduces one reactant gas at a time. In ALCVD, reactants are supplied in pulses, separated from each other by a purge gas or by evacuating the chamber with a vacuum pump.

For example, assuming that two gases AX and BY are used. When the reaction gas AX flows into a reaction chamber, atoms of the reaction gas AX are chemically adsorbed on a substrate, resulting in a layer of A and a surface of ligand X (associative chemisorptions) (step 1). Then, the remaining reaction gas AX is purged with an inert gas (step 2). Then, the reaction gas BY flows in, and a chemical reaction between AX (surface) and BY (gas) occurs only on the surface of the substrate. The Y ligand reacts with the X ligand, releasing XY, resulting in an atomic layer of AB on the substrate (dissociative chemisorptions)(step 3). The remaining gas BY and by-products of the reaction (XY) are purged (step 4). The thickness of the thin film can be increased by repeating the process cycle (steps 1-4) many times.

Because the film can be deposited one monolayer at a time it tends to be conformal and have uniform thickness.

ALCVD has been used to deposit a variety of materials, including II-VI and III-V compound semiconductors, elemental silicon and metals, SiO2, and metal oxides and nitrides. Depending on the process, films can be amorphous, epitaxial or polycrystalline. ALCVD typically has a very low deposition rate, on the order of 1 Å/cycle, where each cycle lasts a few seconds. ALCVD reaction rate at low temperatures can be increased by using highly reactive elements, such as radicals. Such an approach has been described in a paper by K. Hiramatsu, H. Ohnishi, T. Takahama and K. Yamanishi, Formation of TiN Films with Low Cl Concentration by Pulsed Plasma Chemical Vapor Deposition, J. Vac. Sci. Techn. A14(3), 1037 (1996) and patents issuing in 1999 and 2002 to A. Sherman, U.S. Pat. Nos. 5,916,365 and 6,342,277. Their films were grown from gaseous compound by ALCVD with assistance of gas fragments (radicals) created by low-pressure plasma.

As we have mentioned above ALCVD demonstrate remarkable conformality and uniformity. But for practical implementation, particularly in microelectronics, this technology requires a solution to produce films with higher purity and higher throughput. As is well known to those skilled in the art, ALCVD suffers from the disadvantage of an unacceptably high level of residual species (such as chlorine, fluorine or carbon) being retained in the film as well as possible formation of pinholes. For such applications as gate dielectric and diffusion barriers, where the excellent uniformity conformal coatings achievable with ALCVD are most suitable and very low deposition rate is tolerable, chlorine, fluorine and carbon impurities are a major problem on the way to IC industry acceptance. The problem of chlorine, fluorine or carbon contamination is particularly important when the film being deposited is intended to function as a alternative gate dielectric (metal oxide) to replace the thermally grown silicon dioxide on silicon for CMOS, capacitor dielectric for DRAMS, and the like.

Gate dielectrics, which can be as thin as 10-60 Å, are especially susceptible to contamination. The presence of conductive chlorine or carbon will change the gate dielectric's properties, e.g. conductivity. The resultant contaminants cause the normally insulating gate oxide layer to become slightly conductive, e.g. having intolerably high leakage current, thus being unable to function as a gate dielectric. Prevention of high leakage current is precisely the reason why metal oxides with higher dielectric constant tend to be used instead of silicon oxide.

The thinner the deposited film, the greater the sensitivity to changes in conductivity as a result of contamination.

The presence of impurities in diffusion barrier or gate dielectric not only affect their own properties, but also can adversely change the properties of other regions of the electronic device, when contaminants diffuse out of the deposited film.

It is a requirement of the deposition process that the layer be deposited with an absolute minimum of contaminations.

As indicated above, the typical deposition rate of conventional ALCVD is very low a highly desirable goal for any ALCVD-like process is to deposit 1 monolayer per cycle. Higher or lower deposition rates usually manifest higher impurities concentration. For many materials, particularly for metal oxides, much smaller deposition rates are more tolerable and can be as low as 0.1 monolayer per cycle. Still, such low rates can be a serious obstacle for commercialization. The obvious solution is a batch system. Batch systems bring problems of their own. To name a few of them: cross contamination from substrate to substrate and batch-to-batch, inadequate process repeatability from substrate to substrate and batch-to-batch, backside deposition, etc. All of these factors severely affect overall system yield and reliability, and therefore negatively impact net throughput and productivity.

Contrary to conventional CVD, Atomic Layer CVD is self-limiting process. The precursor reactant (e.g., AX) in ALCVD must readily absorb at bonding sites on the growth surface in self-limiting mode, and once adsorbed must readily react with co-reactant (e.g., BY, in self-limiting mode too) to form the desired monolayer, (e.g., AB).

The self-limiting mode is what most distinguishes Atomic Layer CVD from conventional CVD. But it also creates a most notorious problem—impurities. The kinetics of ALCVD reactions depends on the reaction rate between the precursor and a surface reactive site and on the number of available reactive sites. As the reactions advance to completion, the surface is transformed from being totally reactive to a surface of very few reactive sites, i.e., into a non-reactive (self-limiting mode). In many cases, especially when reaction rate is very low, and the deposition cycle is terminated before all sites have reacted, some number of reactive sites are left unchanged at the end of the cycle, creating a source of potential impurities.

Reaction rate is proportional to the product of the probability of the reaction and number of the reaction attempts (hitting frequency). One way to reduce or completely eliminate sites that are left reactive at the end of the cycle is to wait until reaction occurs at all sites. Since this process is stochastic it can takes hours or even days or years to occur. Another approach is to increase reaction probability. This can be done by increasing process temperature or by using different reactant. An increase in temperature could result in opposite effect, since the desorption rate of the surface film formed also increases with temperature. Temperature increase can also be adverse from a manufacturing point of view, since it can be incompatible with a thermal budget of IC manufacturing. Alteration of reactants used in the process is not always possible and often undesirable. Reaction probability can be increased without actual change in precursor by using gas fragments (radicals) created by low-pressure plasma as was described above. But this also has not always been feasible since using low-pressure plasma can cause plasma damage to sensitive devices. The only reliable and trouble-free solution is to increase the hitting frequency (reaction attempts). Conventional Atomic Layer CVD operating range is from about 1 mmTorr to about 1 Torr.

### SUMMARY OF THE INVENTION

The present invention provides extraordinary increases in reaction rates for ALCVD by changing the operating pressure to atmospheric pressure. This will allow orders of magnitude increase (more than 1000 times) in the concentration of reactants available, with consequent enhancement of surface reaction rates. Since hitting frequency is proportional to the precursor pressure (or precursor density), more than 1000 times increase in pressure translates to more than 1000 times higher hitting frequency and, consequently, in proportionally higher reaction rate. Such a large increase in reaction rate will greatly reduce or completely eliminate the number of sites left reactive during processing time. Data shows that level of impurities can be reduced to near zero at very low temperatures if operation is performed at atmospheric pressure.

Reaction rate can be further increase by using atmospheric pressure plasma to create gas fragments (radicals). An Advantage of using atmospheric pressure plasma over low-pressure plasma is that plasma damage can be completely eliminated while the density of radicals created is many orders of magnitude higher at atmospheric pressure than at low-pressure. Detailed description of using atmospheric pressure plasma for device etching and benefits of using atmospheric pressure plasma in IC processing can be found in U.S. Pat. No. 6,218,640 Atmospheric Pressure Inductive Plasma Apparatus issued in 2001 to S. Selitser, incorporated herein by reference.

It is an object of the present invention to provide an atomic or molecular layer deposition apparatus operated at atmospheric pressure and capable of depositing atomic or molecular monolayer or multiple layers of thin film.

It is an object of the invention to facilitate growth of high purity thin film by using atmospheric pressure to increase associative or dissociative chemisorptions of gaseous reactant.

It is another object of the present invention to provide an atomic or molecular layer deposition apparatus operated at atmospheric pressure and capable of depositing sequentially different thin films substantially free of contamination by using separate chambers for each reactant. Separate deposition chambers for each reactant will greatly reduce or almost eliminate deposition of other reactant species on the chamber walls therefore removing a major source of contaminates and particles. Process conditions in each chamber can be individually adjusted to fit physical and chemical processes that take place in each chamber. For example, different temperature can be used for associative and dissociative chemisorptions, for reducing physisorption, etc., therefore facilitating growth of high purity thin film.

It is another object of the present invention to facilitate growth of high purity thin film by using atmospheric pressure plasma to generate very high concentrations of radicals. Using atmospheric pressure plasma will completely eliminate plasma damage to sensitive semiconductor devices that is commonly associated with low-pressure plasma while producing many orders of magnitude higher radical concentrations found in conventional low-pressure plasma.

It is another object of the present invention to facilitate simpler deposition processes and improve throughput by using continuous reactant flows without interruption and without pulsing.

### BRIEF DESCRIPTION OF THE DRAWINGS

FIG. 1 is schematic drawing of an APMLCVD apparatus, capable to deposit atomic or molecular layers at atmospheric pressure.

FIG. 2 is schematic drawing of APMLCVD apparatus with optional radical generator. Radical generator is using atmospheric pressure thermal plasma to generate chemical radicals (fragments).

FIG. 3 is schematic drawing of APMLCVD apparatus that consist of two chambers.

FIG. 4 is schematic drawing of APMLCVD apparatus that consist of two chambers and has movable substrate holder.

FIG. 5 is schematic drawing of APMLCVD apparatus that consist of two chambers and have optional radical generators.

FIG. 6 is schematic drawing of APMLCVD apparatus that divided into two chambers by gas flow.

FIG. 7 is schematic drawing of multichamber APMLCVD apparatus.

FIG. 8 is schematic drawing of multichamber APMLCVD apparatus that use continues reactant flow without pulsing.

FIG. 9 is schematic drawing of multichamber APMLCVD apparatus that use continues reactant flow without pulsing and two injectors in each chamber.

FIG. 10 is schematic drawing of APMLCVD apparatus that consistent of one chamber and use continues reactant flow without interruption.

### DESCRIPTION OF THE PREFERRED EMBODIMENTS

This invention is enhanced variation of ALCVD that overcomes the problems of conventional ALCVD producing high purity film without compromising throughput, conformality, and uniformity.

We term the new and unique process Atmospheric Pressure Molecular Layer CVD (APMLCVD).

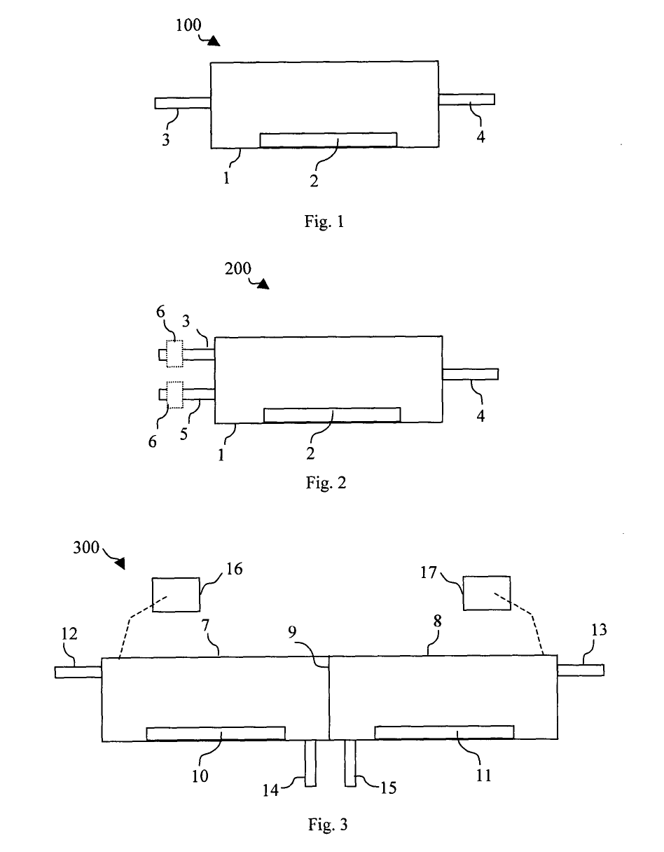

FIG. 1 is cross-sectional schematic view of an embodiment 100 of the present invention, having a chamber 1 which is capable for operation at atmospheric pressure and deposition of one monolayer per cycle. Heated substrate holder 2 located inside of the chamber and can be set for any temperature in the range of 50-800 0C. Reactant gasses and purge gas (not shown) are introduced to the chamber 1 through manifold 3. Reaction at atmospheric pressure between reactants is much more vigorous than at low pressure. Special precaution is taken to prevent any residue to remain in the chamber, manifolds, valves, etc., at the completion of a mono-layer deposition cycle by flushing out the chamber, manifolds, valves, etc., by a purge gas cycle.

Reactant and purge gasses in the embodiment 100 leave the chamber 1 through exhaust 4. To assist in evacuation of residual chemicals during each purging cycle, exhaust 4 can be optionally maintained at differential pressure compare to the chamber 1.

With regard to FIG. 2, there is shown another embodiment of the present invention 200. in addition to the chamber 1, the substrate holder 2 and reactant, purge manifold 3 of FIG. 1, apparatus 200 has a separate reactant, purge gas manifold 5 provided for a second reactant. To prevent reactant residue accumulation in manifold valves and regulators when an additional manifold 5 is provided, purging gas is run through it during each purging cycle.

A second reactant, purging manifold 3 is provided to deliver reactant and purging gas to chamber 2 in an alternative dual reactant/purge process using the embodiment 200. Purging gas is run through both manifolds 3, 5 simultaneously during a purging cycle in a dual reactant, purging process for embodiment 200. This will prevent reactant residue from remaining in stagnant areas of the reactant manifolds 3, 5.

A radical generator 6 (dotted lines) operating at atmospheric pressure can be, optionally, added to one or both manifolds. Such a radical generator can be e.g., an inductive thermal plasma torch, a generator based on glow discharge, DC or RF arc, etc.

FIG. 3 is a schematic view of an embodiment 300 of the present invention apparatus that is capable of operation at atmospheric pressure and has a first chamber 7 and a physically separate second chamber 8. A solid wall 9 in embodiment 300 separates Chambers 7 and 8. Chambers 7 and 8 are each dedicated separately to each reactant used in the deposition process. This physically separated configuration will greatly reduce chances of gas phase reaction between residual reactants left from the previous cycle. Such reactions can contaminate one or both of the chambers and therefore contaminate films later deposited in the chamber.

In addition to greatly reduced chances of gas phase reaction, separation of reactants not only in time but also in space (i.e., separate chambers) will almost completely eliminate deposition process on the reactor walls. One advantage of this structure is the increased number of operating cycles before is becomes necessary to clean a deposition chamber; the necessity for stopping the processing for chamber cleaning becomes very rare or almost unnecessary. A reduction complete elimination of cleaning frequency will greatly increase the tool's throughput and, consequently, reduce the operating cost making it more production worthy.

Each chamber, 7 and 8, has its own dual gas manifold, 12 and 13, (purge, reactant) and separate exhaust, 14 and 15. Heated substrate holders, 10 and 11, are independently controlled and can be set up to different temperatures. Each chamber, 7 and 8, has separate control units, 16 and 17, that independently govern the process condition in each chamber.

If more than two reactants are desired to be used in a particular deposition process sequence, alternative embodiments of apparatus 300 with additional chambers and supporting manifolds (not shown) can be added for each successive reactant or group of reactants.

Substrates can be moved from one chamber to another by a number of different known transport means. One known way to do this is to use a robot mechanism (not shown) to transfer substrates from a substrate holder for one chamber to another substrate holder for another chamber.

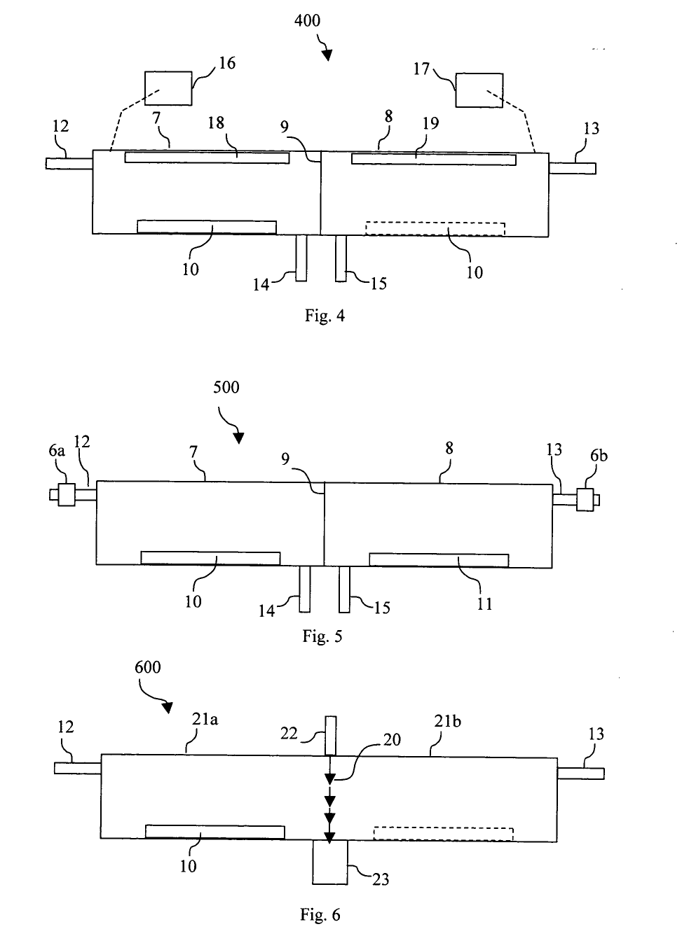

With regard to FIG. 4 an embodiment 400 of the present invention is adapted for the case in which it is more favorable to keep substrates on a substrate holder 10 and to move substrate holder 10 from a first position (solid lines) in 1^{st} chamber 7 to a 2^{nd} position (dotted lines) in 2^{nd} chamber 8. Apparatus 400 includes the 1^{st} & 2^{nd} dual reactant, purge gas manifolds 12, 13, 1^{st} & 2^{nd} exhaust manifolds 14, 15, and 1^{st} & 2^{nd} control units 16, 17, as in the embodiment of FIG. 3. In such situations, if different temperatures are required for each chamber, optional radiative heat sources, 18 and 19, can be installed in each chamber. Alternatively, the embodiment 400 is more favorable in other situations when it is desired to have only one radiative heat source, 18 or 19, and a conventional conductive heater (not shown) incorporated in substrate holder 10. In such case the radiative heater (18, or 19) should be installed in the chamber that requires higher temperature. This will allow heating up a substrate by thermal radiation and cooling it down by thermal conduction and convection. Cycling in temperature should not have noticeable affect on throughput, since heating by thermal radiation is relatively fast and cooling can be performed during purge time assisted by the forced thermal convection of the purge gas. Both heating and cooling of substrates, if desired, is accelerated by using a different (e.g., hotter or colder) temperature for the purge gas after each deposition reaction step in the cycle.

With reference to FIG. 5, an alternate embodiment of the apparatus 300 of FIG. 3 has optional radical generators, 6a and 6b added to one or both manifolds 12, 13. The radical generators, 6a and 6b, operate at atmospheric pressure, Such radical generators include an inductive thermal plasma torch, a generator based on glow discharge, DC or RF arc, etc.

Referring to FIG. 6, in another embodiment of the present invention, an apparatus 600 provides benefits of higher cleanliness, higher purity growth facilitation, and increased chambers 21a, 221b by inert purge gas from nozzle 22 used to separate reaction chambers. Strong separating flow from nozzle 22 can also be used as additional substrate purge when a substrate is moving from one reaction chamber 21a to another 221b. This will greatly enhance removal of residual gas and reaction bi-products from the surface of the substrate. Thus, improving growth of impurity-free thin films.

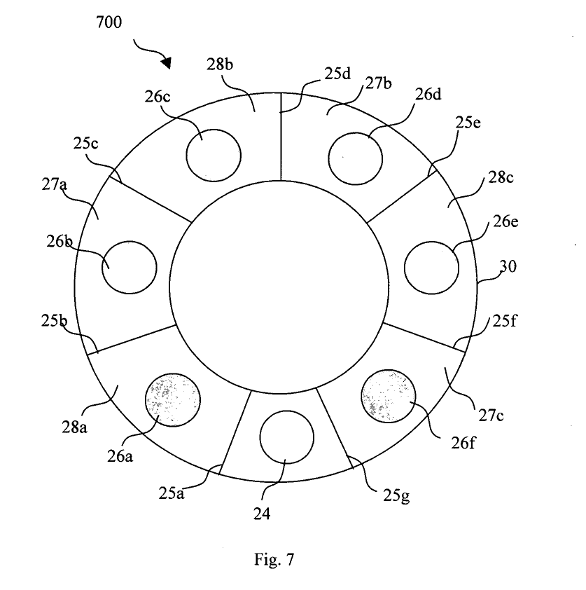

With regard to FIG. 7 there is shown a multi-chamber embodiment 700 of the present invention. Moving substrates or substrate holders back and forth between two chambers is not always commercially and/or technically the best embodiment. In some situations it could be more beneficial and could improve throughput substantially to have a multi-chamber tool 700 instead of two separate chambers or one divided chamber apparatus. In the multi-chamber arrangement of the apparatus 700 the number of chambers, Nc, equals six; i.e., chambers 28a, 28b, 28c, 28d, 28e, 28f. In the embodiment 700 of the present invention, substrates 26a, 26b, 26c 26d, 26e, 26f will be moved sequentially from one chamber to the next chamber by a rotating substrate holder track mechanism 30, pausing in each chamber for a single monolayer reactant-processing step. The number of chambers should be even number if two or more reactants are required for each layer deposition and separation of at least one reactant is process beneficial.

In multi-chamber apparatus 700, after substrate 26a is loaded into loading station 24, it will be moved to the first processing chamber 28a by the track mechanism 30, examples of which are well known in industry. After processing with a first reactant (e.g., AX) in chamber 28a, substrate 26a will be moved to the next processing chamber 28b where a second reactant (e.g., BY) will finish deposition of the first monolayer.

This process will be repeated in the next two chambers 28c and 28d, then in 28e and 28f. If reactant separation is unnecessary or not beneficial, the number of chambers can be any number and deposition of a monolayer will be done in each chamber the same way as described above for FIG. 1. The total number of chambers, Nc, can be also an integral multiplier of the number of reactants if processing each reactant should be separated and more then two reactants are required.

Separators 25a, 25b, 25c, 25d, 25e, 25f, 25g are positioned between the chambers. The separators can be solid as shown in FIGS. 3, 4 or 5 or be determined by gas flow curtains as shown in FIG. 6. The Multi-chamber apparatus 700 substantially improves throughput compared to a single chamber or two-chamber apparatus.

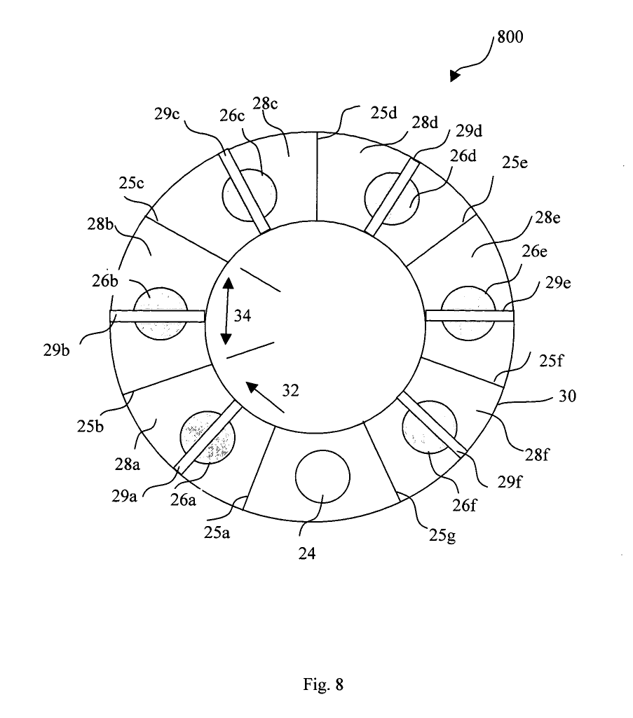

Another embodiment 800 of the present invention is indicated with reference to FIG. 8 Apparatus 800 independently processes each substrate with each reactant without stopping substrate movement. Apparatus 800 includes the load/unload station 24, the separate chambers 28a-f and separators 25a-g, and the track mechanism 30 shown in FIG. 7. The advanced intrinsic uniformity feature of AMLCVD is accomplished in system 800 by linear injectors 29a, 29b, 29c, 29d, 29e, 29f, as reactant gas sources. In conventional CVD, deposited film thickness (e.g. uniformity) is directly proportional to the time spent under an injector and depends on the gas flow.

The arrangement of the present invention shown in FIG. 8 would be very difficult to accomplish or impossible to commercialize for conventional CVD. Since deposit thickness in APMLCVD does not increase after surface saturation, independent of how long the substrate spends under the reactant source, it is not necessary to take any precautions to adjust reactant gas flow from the injectors 29a-f or substrate speed form mechanism 30 as long as substrate motion is slow enough to saturate the substrate area under each injector.

A rough calculation can be made to see what upper speed of substrate motion should be. If saturation of substrate surface required s seconds and effective length (in direction of movement) covered by injector is x, the maximum speed can be estimated as x/2s. In many processes saturation time is a few seconds and effective length (which is strongly depends on actual design of the injector) can be estimated as a few centimeters, which gives an estimated speed of about a few centimeters per second. This number is stated here only as an example and should be calculated for each particular process and linear injector design.

Each injector, 29a, 29b, 29c, 29d, 29e, 29f, on FIG. 8 will be used for one reactant only. This will allow continuous motion of the substrates 26a, 26b, 26c, 26d, 26e, and 26f from chamber to chamber without stopping. That is, from chamber 28a to 28b, from 28b to 28c, etc. To simplify overall system design and improve throughput, purging gas flow and exhaust manifolds [not shown] are included for each injector 29a, 29b, 29c, 29d, 29e, and 29f in the apparatus 800. Such manifolds can be incorporated, for example, as indicated in FIG. 6 schematically by purge nozzle 22 and exhaust manifold 23.

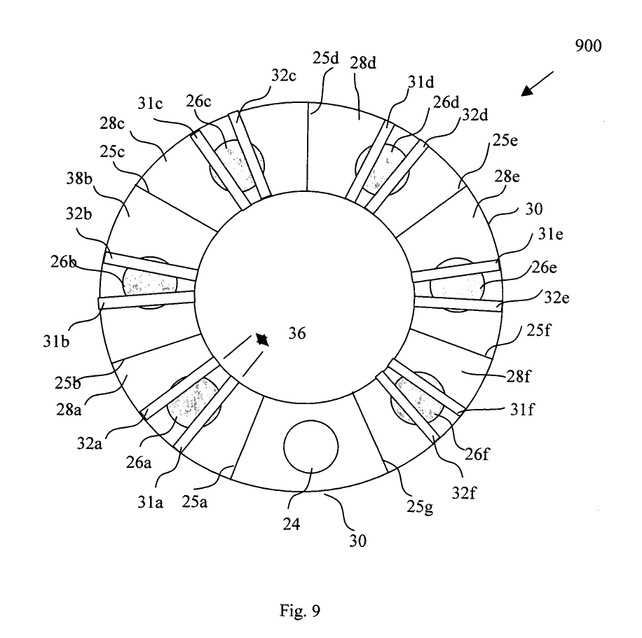

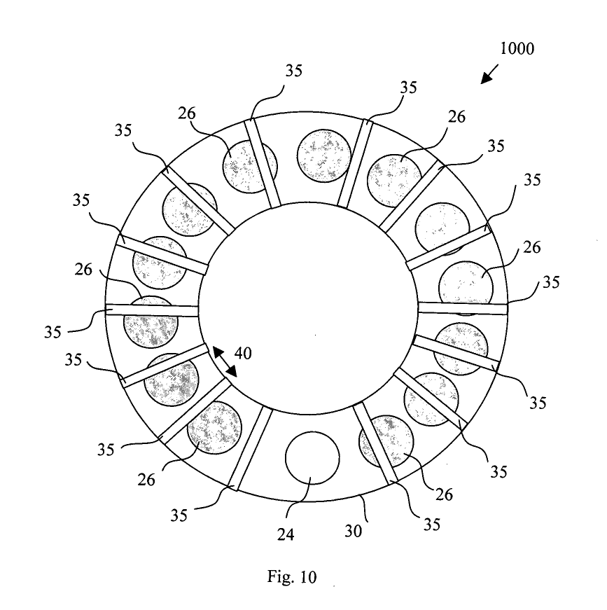

Referring now to FIG. 9, there is shown another embodiment 900 of the present invention. In some monolayer deposition processes situations it could be more beneficial to have not just one linear injector, but instead to have two or more per chamber. Embodiment 900 has such pairs of injectors in each chamber, i.e., a first injector 31a, and second injector 32a in the first chamber 28a and another first injector 31a, and another 2^{nd} injector 32a in the second chamber 28ba. Purity and quality of the films deposited on substrates 26a -26f depends on a number of things, particularly how well the substrate surface is saturated with reactant in each chamber, the degree of completion of the chemisorptions at each available surface site and level of removing physisorbed reactant for the next chemisorption step, as we described above.

An additional process step that removes physisorbed reactant left after first injector, 31a, and −31f will greatly improve film quality. This is accomplished by incorporating purging gas (as described in FIG. 8) in each first injector following the reactant from the first injector and then sequentially re-inject the same reactant with the second injector 31b-31f in the same chamber, In conventional Atomic Layer CVD the addition of additional purging and re-injecting steps will diminish already poor process throughput and make commercialization very difficult. In the APMLCVD embodiment 900 of the present invention adding additional purging and re-injecting steps (e.g. by linear injectors 32a, b, c and 34a, b, c) will be limited only by space and will have no effect on throughput. In the embodiment 900 quality of the film can be improved without sacrificing system throughput.

In some process situations overall system performance can be improved by completely removing chamber's walls. Referring now to FIG. 10 there is shown a schematic diagram of an embodiment 1000 of a multi-mono-layer deposition apparatus in accordance with the present invention. A series of separated injectors 35 are spaced around rotating circular substrate holder track 30. Substrates 26 are sequentially loaded on the track 30 at a substrate load/unload station 24. The track 30 rotates in one direction, carrying the substrates 26 in sequence under each successive injector 35 at a speed that ensures saturation by reactants flowing from the injectors. After passing under the last injector of the series, substrates 26 are unloaded at station 24.

Each injector 35 incorporates independently operated reactant, purging and exhaust gas manifolds and controls (not shown) and acts as one complete mono-layer deposition and reactant purge cycle for each substrate 26 as if passes there under in the multi-mono-layer deposition process. The spacing of the injectors, indicated by double-head arrow 40 is selected so that cross-contamination from adjacent injectors is prevented by purging gas flows and exhaust manifolds incorporated in each injector 35. The reactants flowing from each injector may be all different, or all the same or some combination of same and different reactants.

Persons having skill in the art will recognize the flexibility in process design that embodiments of the present APMLCVD invention provides, and particularly the embodiment 1000. Depending on the particular multi-monolayer deposition processes desired, the number of injectors (and the reactants and purge gasses controlled thereat) participating in one monolayer deposition can be easily varied from one process to another. This will greatly increase system flexibility and consequently broaden its commercial potential.

1. An ALCVD process, comprising:
A gas sequence cycle at atmospheric pressure comprising:
a first step of directing a reactant flow to saturate a substrate surface;
a second step of directing a purge gas flow to purge said reactant from said surface, in which said second step follows said first step in time;
a step of exhausting said purge gas and said reactant from said substrate through a fixed exhaust associated with said Gas Sequence cycle.

2. The ALCVD process set forth in claim 1, wherein said substrate is at a fixed location.

3. The ALCVD process set forth in claim 1, comprising:
a second Gas Sequence cycle at atmospheric pressure comprising:
a 3rd step of directing a 2nd reactant flow to saturate said substrate surface;
a 4th step of directing a 2nd purge gas flow to purge said reactant from said surface, in which said 4th step follows said 3rd step in time;
a step of exhausting said 2nd purge gas and said 2nd reactant from said substrate through a fixed exhaust associated with said second Gas Sequence cycle.

4. The ALCVD process set forth in claim 3, wherein said substrate is at the same fixed location during said 1st and said 2nd Gas Sequence cycle.

5. The ALCVD process set forth in claim 3, wherein said substrate is at a 1st location during said 1st Gas Sequence cycle and said substrate is at a 2nd location during said second Gas Sequence cycle.

6. The ALCVD process set forth in claim 5, wherein said 1st location and said 2nd location are fixed.

7. The ALCVD process set forth in claim 6, wherein said 1st location and said 2nd location are fixed inside a single deposition chamber.

8. The ALCVD process set forth in claim 6, wherein said 1st location and said 2nd location are fixed inside separate 1st and 2nd deposition chambers.

9. The ALCVD process set forth in claim 8, wherein said 1st Gas Sequence is directed by a 1 st manifold associated with said 1st chamber and said 2nd Gas Sequence is directed by a 2nd manifold associated with and said 2nd chamber.

10. The ALCVD process set forth in claim 5, wherein said 1st location and said 2nd location are moved laterally adjacent to said gas flows during said 1st, 2nd, 3rd and 4th steps by means for moving said substrate.

11. The ALCVD process set forth in claim 5, wherein said 1st Gas Sequence cycle and said 2nd Gas Sequence cycle are separated to prevent gas phase reaction between said 1st reactant flow and said 2nd reactant flow.

12. The ALCVD process set forth in claim 8, wherein said separation is a spatial separation of distance sufficient to prevent said gas phase reaction.

13. The ALCVD process set forth in claim 5, wherein said separation is a time interval of sufficient length sufficient to prevent said gas phase reaction.

14. The ALCVD process set forth in claim 5, wherein said separation is provided by a physical barrier interposed between said 1st locations and said 2nd location sufficient to prevent said gas phase reaction.

15. The ALCVD process set forth in claim 5, wherein said separation provided by a gas flow curtain interposed between said 1st location and said 2nd location sufficient to prevent said gas phase reaction.

16. the ALCVD process set forth in claim 10, wherein said 1st Gas Sequence cycle and said 2nd Gas Sequence cycle are separated to prevent gas phase reaction between said 1st reactant flow and said 2nd reactant flow.

17. The ALCVD process set forth in claim 16, wherein said separation is a spatial separation of distance sufficient to prevent said gas phase reaction.

18. The ALCVD process set forth in claim 16, wherein said separation is a time interval of sufficient length sufficient to prevent said gas phase reaction.

19. The ALCVD process set forth in claim 16, wherein said separation is provided by a physical barrier interposed between said 1st locations and said 2nd location sufficient to prevent said gas phase reaction.

20. The ALCVD process set forth in claim 16, wherein said separation is provided by a gas flow curtain interposed between said 1st location and said 2nd location sufficient to prevent said gas phase reaction.

21. The ALCVD process set forth in claim 16, wherein said separation is provided by a 1st manifold associated with said 1st Gas Sequence and a spaced apart 2nd manifold associated with said 2nd Gas Sequence.

22. The ALCVD process set forth in claim 21, comprising:
a movable substrate holder, comprising:
means for moving said laterally passing substrate adjacent to said reactant gas manifold so that, said substrate receives said substantially linear
reactant gas pattern flowing across its face, and further, to move said substrate adjacent to and laterally passing said purge gas and exhaust manifold while said purge gas is purging said reactant gas from said substrate and said exhaust manifold is exhausting said purged reactant gas and said purge gas.
wherein said 1st manifold and said 2nd manifold are linear gas manifolds comprising:
a reactant gas manifold arranged to inject a continuous reactant gas flow at atmospheric pressure disposed in a substantially linear pattern flowing across the face of an adjacent laterally passing substrate;
an atmospheric pressure purge gas and exhaust manifold spaced adjacent to said reactant gas manifold and arranged to direct a continuous purge gas flow across said face of said adjacent laterally passing substrate, and to exhaust said reactant gas and said purge gas after flowing across said laterally passing substrate;
